(19) United States
(12) Patent Application Publication
(10) Pub. No.: US 2024/0186764 A1
(43) Pub. Date: Jun. 6, 2024

(54) SPACER FOR ATTACHING COEFFICIENT OF THERMAL EXPANSION MISMATCHED COMPONENTS

(71) Applicant: Lumentum Operations LLC, San Jose, CA (US)

(72) Inventors: Jian CHEN, San Jose, CA (US); Andy QIU; Sukhbir BAJWA, San Jose, CA (US); Jarin PETWONG, Nonthaburi (TH)

(21) Appl. No.: 17/757,819

(22) PCT Filed: Dec. 22, 2021
(86) PCT No.: PCT/CN2021/140502

§ 371 Date: Dec. 29, 2022

(30) Foreign Application Priority Data
Jun. 21, 2021 (WO) PCTCN2021101149

(51) Int. Cl. H01S 5/02315; B23K 1/00; B23K 101/40; H01S 5/02216; H01S 5/02251; H01S 5/02325

(52) U.S. Cl. CPC H01S 5/02315; B23K 1/0016; H01S 5/02216; H01S 5/02251; H01S 5/02325; B23K 2101/40

(57) ABSTRACT

In some implementations, an optical device may include a base with a first coefficient of thermal expansion (CTE). The optical device may include an opto-mechanical component with a second CTE attached to a surface of the base via a solder layer. The first CTE and the second CTE may differ by greater than a threshold amount. A spacer may be disposed within the solder layer to attach the opto-mechanical component to the base.

### CROSS-REFERENCE TO RELATED APPLICATION

This patent application claims priority to Patent Cooperation Treaty (PCT) Patent Application No. PCT/CN2021/101149, filed on Jun. 21, 2021, and entitled “CONTROL SOLDER BOND LINE THICKNESS WITH SQUEEZED GOLD BUMP SPACE.” The disclosure of the prior application is considered part of and is incorporated by reference into this patent application.

### TECHNICAL FIELD

The present disclosure relates generally to optical devices and to a spacer for attaching coefficient of thermal expansion mismatched components in a laser package.

### BACKGROUND

Optical devices, such as laser packages, may include multiple components attached to a substrate. For example, an optical device may include a base structure onto which is mounted one or more opto-mechanical components, such as a chip-on-submount (CoS) assembly, a fiber mount, a carrier, a prism, a lens, or a waveguide device, among other examples. Each of the one or more opto-mechanical components may be precisely positioned to enable alignment to an optical path. Precise alignment may improve performance of the optical device, such as by improving an efficiency of optical communication when the optical device is an optical communication device. The one or more opto-mechanical components may be attached to the base structure, in a desired position and alignment, using a layer of solder.

### SUMMARY

In some implementations, an optical device includes a base with a first coefficient of thermal expansion (CTE); and an opto-mechanical component with a second CTE attached to a surface of the base via a solder layer, wherein the first CTE and the second CTE differ by greater than a threshold amount, and wherein a spacer is disposed within the solder layer to attach the opto-mechanical component to the base.

In some implementations, a method includes providing a spacer on a first surface of a first component of an optical device: and attaching a second surface of a second component of the optical device to the first surface of the first component of the optical device, wherein a solder layer is disposed between a first portion of the first surface and a second portion of the second surface, and wherein the spacer is disposed within the solder layer between the first surface and the second surface.

In some implementations, an optical device includes a base with a first CTE; a fiber mount with a second CTE attached to a surface of the base via a first solder layer, wherein the first CTE and the second CTE differ by greater than a threshold amount, and wherein a first set of spacers is disposed within the first solder layer to attach the fiber mount to the base: and a chip-on-submount (CoS) with a third CTE attached to the surface of the base via a second solder layer, wherein the first CTE and the third CTE differ by greater than the threshold amount, and wherein a second set of spacers is disposed within the second solder layer to attach the CoS to the base.

In some implementations, an optical device includes a base with a first CTE: a first opto-mechanical component with a second CTE attached to a surface of the base via a first solder layer, wherein the first CTE and the second CTE differ by greater than a threshold amount, and wherein a first spacer is disposed within the first solder layer to attach the first opto-mechanical component to the base; and a second opto-mechanical component with a third CTE attached to the surface of the base via a second solder layer, wherein the first CTE and the third CTE differ by greater than the threshold amount, and wherein a second spacer is disposed within the second solder layer to attach the second opto-mechanical component to the base.

### BRIEF DESCRIPTION OF THE DRAWINGS

FIG. 1 is a diagram of an example associated with an optical device, as described herein.

FIG. 2 is a diagram of an example associated with an optical device, as described herein.

FIG. 3 is a diagram of an example associated with a spacer disposed between components of an optical device, as described herein.

FIGS. 4A and 4B are diagrams of an example associated with attaching components of an optical device, as described herein.

FIG. 5 is a flowchart of an example processes relating to attaching components of an optical device, as described herein.

### DETAILED DESCRIPTION

The following detailed description of example implementations refers to the accompanying drawings. The same reference numbers in different drawings may identify the same or similar elements.

In opto-electronic or opto-mechanical packaging, solder is used to bond components together and hold the components in a position of alignment. Moreover, solder may be used to provide electrical conductivity for the components (e.g., to electrically couple the optical components) or to provide thermal conductivity for the optical components (e.g., to allow heat to transfer from one component to another component. A mismatch between coefficients of thermal expansion (CTEs) of different components, which are aligned using a thin solder bond line, can lead to thermal stress. For example, an opto-mechanical component, such as a fiber mount, a carrier, a prism, a lens, a waveguide device, a metal layer, or a chip-on-submount (CoS), among other examples, may have a different CTE than a base structure of an optical device, resulting in thermal stressing of a solder joint attaching the opto-mechanical component to the base structure. In this case, solder bond line thickness of less than approximately 5 micrometers (μm) may be particularly susceptible to cracking during temperature cycling (e.g., under thermal stress). By increasing a solder bond line thickness (e.g., to greater than 40 μm), thermal stress may be mitigated for components with mismatched CTEs (e.g., CTEs that differ by more than a threshold amount.

However, increasing a solder bond line thickness can result in solder creep. Solder creep may result in a misalignment of components of an optical device. For example, when a first opto-mechanical component is soldered to a base structure in alignment with a second opto-mechanical component that is soldered to the base structure, solder creep may result in the first opto-mechanical component losing alignment with the second opto-mechanical component. In this case, as the solder bond line thickness increases, it may be increasingly difficult to control an exact thickness of the solder bond line and, accordingly, an alignment of components attached using the solder bond line. In other words, a thicker solder bond line may have more variance in its exact thickness, which may result in alignment issues. Alignment issues may cause poor performance for the optical device, such as by interrupting or reducing an efficiency of optical communications.

Some implementations described herein enable control of a solder bond line thickness with minimal solder creep and resistance to cracking. For example, a spacer may be disposed within a solder bond line (e.g., between a base and an opto-mechanical component that is to be attached to the base using the solder bond line). In this case, the spacer has a precisely controlled thickness and serves as a stand-off between the base and the opto-mechanical component, thereby precisely controlling a distance between the base and the opto-mechanical component (e.g., and preventing or reducing solder creep) while allowing for an increased thickness solder bond line to reduce a likelihood of cracking. In this way, an optical device achieves improved reliability (from reduced likelihood of solder cracking) and improved performance (from a reduced likelihood of misalignment) relative to optical devices that do not include a spacer disposed within a solder bond line.

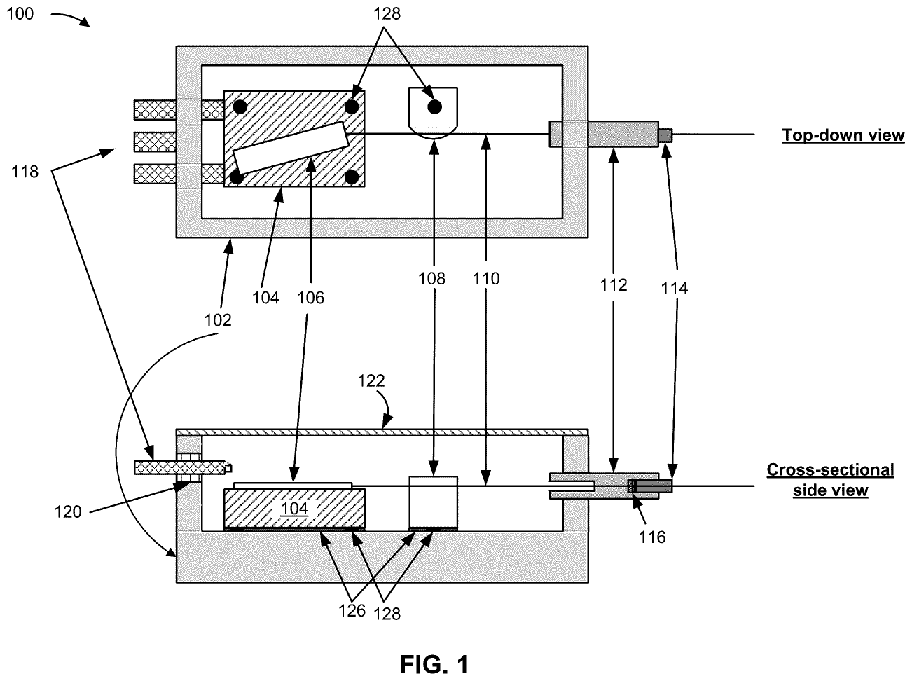

FIG. 1 is a diagram of an example of an optical device 100. As shown in FIG. 1, optical device 100 is a single mode pump laser package. Although some implementations are described herein in terms of a single mode pump laser package, implementations described herein may be applied to high precision packaging designs for other types of optical devices, lasers, optical components, or opto-mechanical components (e.g., which may include carriers, prisms, lenses, waveguide devices, emitters, vertical cavity surface emitting lasers (VCSELs), lasers, laser drivers, and/or metallization layers associated therewith), among other examples.

As further shown in FIG. 1, optical device 100 may include a package 102, which may form a base onto which one or more opto-mechanical components are attached. For example, a submount 104 with a chip 106 (e.g., forming a chip-on-submount (CoS) assembly 104/106 may be attached to package 102. Similarly, a fiber mount 108 may be attached to package 102. In some implementations, the one or more opto-mechanical components may have a CTE match with package 102, such as having CTEs with 25% of a CTE of package 102. In some implementations, the one or more opto-mechanical components may have a CTE mismatch with package 102. For example, package 102 may have a copper tungsten (CuW) base (e.g., 10/90 Copper/Tungsten) with a CTE (in 10⁻⁶/Kelvin (K)) of 5.6, and fiber mount 108 may include a borosilicate glass material with a CTE of 3.3. In some implementations, package 102 may be formed from multiple components. For example, package 102 may have a first material forming the base of package 102 and a second material forming another portion of package 102. In this case, the base of package 102 may have a CTE mismatch with an opto-mechanical component that is to be attached thereto, such as CoS assembly 104/106 or fiber mount 108. In some implementations, a CTE mismatch may include having a threshold difference between CTE values. For example, a CTE mismatch between materials may occur when a first CTE (e.g., of package 102) differs from a second CTE or a third CTE (e.g., of CoS assembly 104/106 with a second CTE or fiber mount 108 with a third CTE) by greater than a threshold amount, such as greater than 1.5, greater than 2.0, or greater than 2.5, among other examples.

In some implementations, optical device 100 may further include an optical fiber 110 (e.g., associated with a fiber tail assembly (FTA)), an output 112 (e.g., a snout which forms and/or provides a passthrough for package 102 and which includes an epoxy end 114 and a glass solder seal 116), one or more electrical inputs 118 in one or more sealed openings 120, and a lid 122 to seal package 102 (e.g., forming a hermetic seal to protect, for example, CoS assembly 104/106 and fiber mount 108).

As further shown in FIG. 1, optical fiber 110 may be aligned with chip 106, fiber mount 108, and output 112, among other examples. For example, chip 106 and fiber mount 108 may be precisely aligned in, for example, a vertical direction with output 112 and optical fiber 110. In this case, to achieve the precise vertical alignment, chip 106 and/or fiber mount 108 may be attached to a surface of package 102 using a solder layer 126 and a set of spacers 128. For example, a spacer 128 may be disposed within (or surrounded by) solder layer 126 and form a stand off between opposing surfaces of package 102 and an opto-mechanical component attached thereto (e.g., CoS assembly 104/106 or fiber mount 108), thereby controlling a thickness of solder layer 126 and a corresponding height of the opto-mechanical component above a surface of package 102. In this case, an accuracy with which a height of spacer 128 is manufactured may be higher than an accuracy that can be achieved using only solder in a gap between package 102 and an opto-mechanical component attached thereto. In this way, by using the set of spacers 128 to control the thickness of solder layer 126 and the resulting height of opto-mechanical components (e.g., CoS assembly 104/106 or fiber mount 108) above a surface of package 102, optical device 100 achieves an alignment tolerance of less than or equal to +/−5 micrometers (μm) for the opto-mechanical components in the vertical direction.

As indicated above, FIG. 1 is provided as an example. Other examples may differ from what is described with regard to FIG. 1.

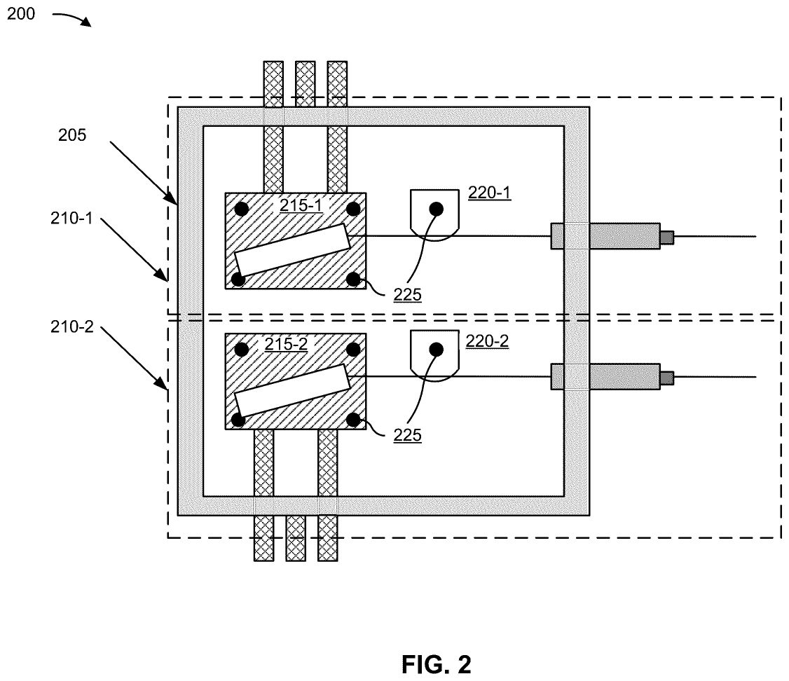

FIG. 2 is a diagram of an example of an optical device 200. As shown in FIG. 2, optical device 200 is a laser package with multiple optical fibers and multiple fiber mounts (e.g., for multiple emitters).

As further shown in FIG. 2, optical device 200 may include a package 205, which may form a base onto which one or more opto-mechanical components are attached. For example, package 205 may include a first device sub-assembly 210-1 and a second device sub-assembly 210-2, each of which includes one or more opto-mechanical components attached to the base of package 205. For example, first device sub-assembly 210-1 includes a first CoS assembly 215-1 and a first fiber mount 220-1 (e.g., for a first emitter) and a second device sub-assembly 210-2 includes a second CoS assembly 215-2 and a second fiber mount 220-2 (e.g., for a second emitter). In this case, each opto-mechanical component includes one or more spacers 225 to control vertical alignment to within a threshold tolerance, as described in more detail herein.

As indicated above, FIG. 2 is provided as an example. Other examples may differ from what is described with regard to FIG. 2.

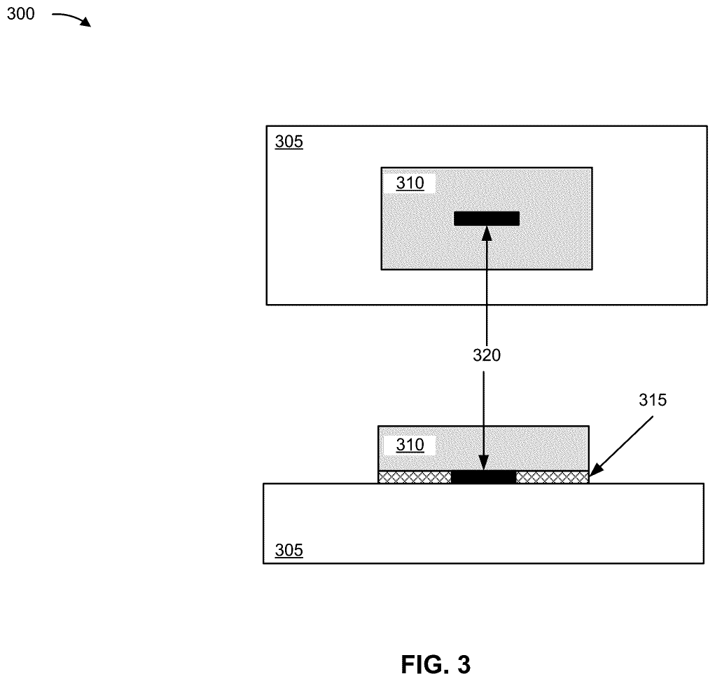

FIG. 3 is a diagram of an example 300 associated with a spacer disposed between components of an optical device. As shown in FIG. 3, a base 305 may attach to an opto-mechanical component 310 (e.g., a fiber mount) via a solder layer 315 into which is embedded a spacer 320.

In some implementations, solder layer 315 is associated with less than a threshold thickness. For example, solder layer 315 may have a thickness of less than or equal to 5 μm. In this case, the thickness of solder layer 315 may correspond to a thickness of spacer 320, which is embedded in solder layer 315. By using spacer 320 to control the thickness of solder layer 315, the thickness of solder layer 315 may be controlled more precisely, thereby achieving a relatively tight alignment tolerance for opto-mechanical component 310 to one or more other opto-mechanical components. By using a relatively thin solder layer 315 (e.g., a solder layer less than or equal to 20 μm, less than or equal to 10 μm, or less than or equal to 5 μm), an effect of solder creep on the alignment is reduced, thereby enabling maintenance of the tight alignment tolerance after initial manufacture.

In some implementations, spacer 320 forms a standoff between opto-mechanical component 310 and base 305. For example, base 305 may be disposed against a first surface of spacer 320 and opto-mechanical component 310 may be disposed against a second surface of spacer 320 (e.g., with no or a small amount of solder layer 315 between surfaces of spacer 320 and base 305 or opto-mechanical component 310, respectively). This may control a size of the gap between base 305 and opto-mechanical component 310 (and, as described herein, a size of solder layer 315) with a reduced likelihood of cracking and failure relative to a solder-only gap.

As indicated above, FIG. 3 is provided as an example. Other examples may differ from what is described with regard to FIG. 3.

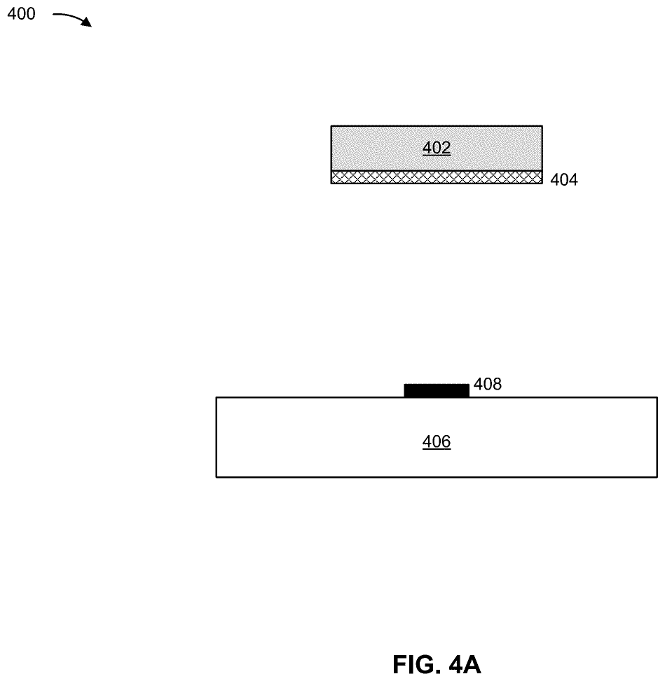

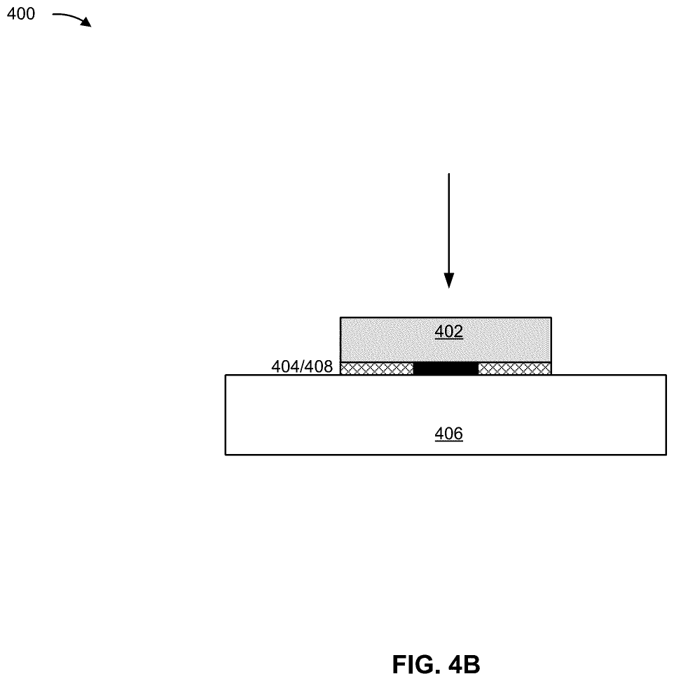

FIGS. 4A and 4B are diagrams of an example 400 associated with attaching components of an optical device. As shown in FIG. 4A, example 400 includes opto-mechanical component 402 with a solder layer 404 on a surface of opto-mechanical component 402 and a base 406 (e.g., of an optical device) with a spacer 408 disposed on a surface of the base 406. In some implementations, solder layer 404 may be a solder preform. For example, solder layer 404 may be deposited on a surface of opto-mechanical component 402 with approximately the same thickness as spacer 408. In some implementations, spacer 408 may be formed using a wire bonder. In some implementations, spacer 408 may be the ball or wedge left behind after the wire is removed (after forming a wire bond to the surface of base 406). For example, an assembly device (e.g., a wire bonder) may attach a configured amount of material as a ball or wedge (e.g., with a configured diameter that is, for example, in a range of 10 to 200 microns and a configured height that is within a threshold tolerance, such as between 8 μm and 15 μm) to the surface of base 406 to form spacer 408. In this case, spacer 408 may be independent of base 406 rather than being formed by shaping base 406 to have a raised area of base 406 forming a spacer relative to another area of base 406. In this way, a material of spacer 408 may be selected to have a CTE match with, for example, opto-mechanical component 402. In another example, spacer 408 may have an integral formed spacer that is an integral part of a surface of base 406 (e.g., from the same or a different material as other parts of base 406). In another example, spacer 408 may be formed by patterning a layer of material deposited on a surface of base 406.

In some implementations, multiple spacers 408 (e.g., multiple, discrete spacer sections of a single spacer) may be formed on the surface of base 406. For example, depending on a size, material strength, or configuration of opto-mechanical component 402 and base 406, multiple spacers 408 may be disposed to ensure that opposing surfaces of base 406 and opto-mechanical component 402 are substantially in parallel across a complete area of opto-mechanical component 402. In some implementations, multiple spacers 408 may be formed on the surface of base 406 to form multiple attachment points for receiving multiple different opto-mechanical components 402. For example, a first group of spacers 408 may be wire bonded to the surface of base 406 for receiving a CoS assembly and a second group of spacers 408 may be wire bonded to the surface of base 406 for receiving a fiber mount. In some implementations, the first group of spacers 408 and the second group of spacers 408 may be formed from different materials or from the same material.

Additionally, or alternatively, spacer 408 may be formed from a particular material, such as a metallic material (e.g., a gold material, a nickel material, or an aluminum material) or a dielectric material, among other examples. In some implementations, spacer 408 may be associated with a particular shape, such as a ball structure shape (e.g., an approximately spherical shape), a bump structure shape (e.g., an approximately hemispherical shape), or a pillar structure shape (e.g., a cylindrically shaped pillar with a circular cross-section, or a rectangularly shaped pillar with a non-circular cross-section), among other examples.

As shown in FIG. 4B, opto-mechanical component 402 may be pressed against base 406. For example, an assembly device (e.g., a die bonder) may heat solder layer 404 (e.g., to a melting temperature to allow bonding) and may mount opto-mechanical component 402 solder side down (e.g., with solder layer 404 directed toward base 406 and spacer 408). In this case, the assembly device may apply compressive force, such that a portion of solder layer 404 is squeezed out from between opto-mechanical component 402 and base 406 (e.g., as a result of pressing opto-mechanical component 402 and base 406 together) and may be displaced by a volume of spacer 408.

In some implementations, the die bonder may maintain opto-mechanical component 402 and base 406 in alignment (e.g., pressed together, separated by spacer 408 and with solder layer 404 in a gap between opto-mechanical component 402 and base 406). For example, the die bonder may statically hold, for a configured dwell time, the opto-mechanical component and base 406 in position with spacer 408 (e.g., substantially parallel to each other and, by applying compressive force, at a fixed spacing controlled by a size of the spacer 408) controlling a gap size. In this case, the die bonder may reduce an amount of heating applied to solder layer 404 to cause solder layer 404 to solidify and attach opto-mechanical component 402 to base 406. In some implementations, the spacer 408 may remain under compressive force after die bonding is completed. For example, when solder layer 404 solidifies, solder layer 404 may hold opposing surfaces of opto-mechanical component 402 and base 406 against surfaces of spacer 408, such that spacer 408 is being compressed by opto-mechanical component 402 and base 406.

In some implementations, another material may form at an interface between the solder layer 404 and the spacer 408 (e.g., in the presence of solder layer 404 and spacer 408 as a result of heating solder layer 404 and spacer 408 and compressing solder layer 404 and spacer 408). For example, solder layer 404 may include a first material and spacer 408 may include a second material, and a third material (e.g., an inter-diffused intermediate material, such as an intermetallic compound or alloy) may form at the interface of the solder layer 404 and the spacer 408 when the opto-mechanical component 402 is attached to the base 406. In this case, the first, second, and third materials may have different melting temperatures. For example, spacer 408 may remain solid at a temperature at which solder layer 404 melts, thereby ensuring that spacer 408 does not deform when opto-mechanical component 402 is attached to base 406. Similarly, the inter-diffused intermediate material may also remain solid at the temperature at which solder layer 404 melts. In this case, a first opto-mechanical component 402 may be attached to base 406 by melting a first solder layer 404, resulting in the formation of the inter-diffused intermediate material. When a second opto-mechanical component 402 is also to be attached to base 406 by melting a second solder layer 404, the inter-diffused intermediate material (formed in the vicinity of the first opto-mechanical component 402 while attaching the first opto-mechanical component 402) may remain solid, thereby maintaining a position of the first opto-mechanical component 402 relative to base 406 while the second opto-mechanical component 402 is being attached to base 406. In other words, a temperature may be returned to a melting temperature for solder (e.g., to attach another opto-mechanical component to the base 406 using another solder layer and another spacer) and the inter-diffused intermediate material may remain solid and prevent movement of the first opto-mechanical component 402. Additionally, or alternatively, manufacture can include attaching a second opto-mechanical component 402 to a surface of a first opto-mechanical component 402 (e.g., attaching a fiber to a fiber mount, attaching a lens to a mount, or attaching a waveguide device to a mount, among other examples) without altering an alignment of the first opto-mechanical component 402 to base 406.

In this way, by preventing solder layer 404 from melting during subsequent attachment steps, the inter-diffused intermediate material maintains an alignment of opto-mechanical component 402 with base 406 by preventing movement of opto-mechanical component 402 with respect to base 406 as could occur if solder layer 404 melted. In other words, multiple opto-mechanical components 402 can be attached to base 406 in a configured alignment without subsequent attachment steps altering an alignment achieved in previous attachment steps.

In some implementations, the inter-diffused intermediate material layer may form at the interface between the solder layer 404 and the opto-mechanical component 402. In some implementations, the inter-diffused intermediate material layer may form at the interface between the solder layer 404 and base 406.

As indicated above, FIGS. 4A and 4B are provided as an example. Other examples may differ from what is described with regard to FIGS. 4A and 4B.

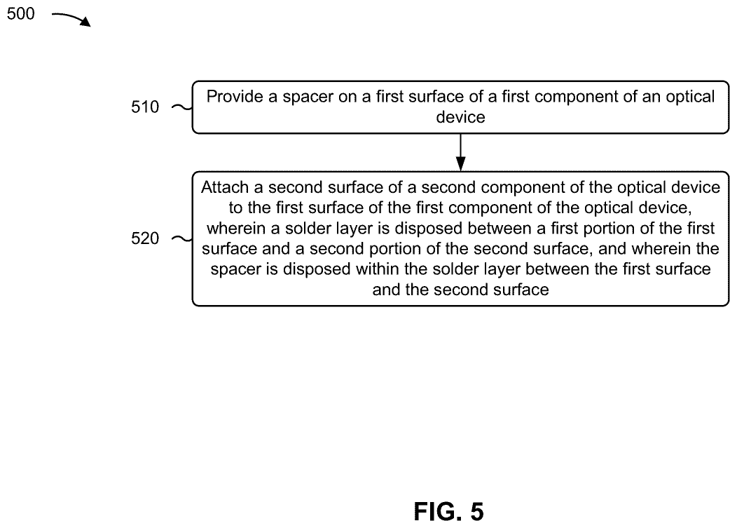

FIG. 5 is a flowchart of an example process 500 associated with using a spacer for attaching coefficient of thermal expansion mismatched components. In some implementations, one or more process blocks of FIG. 5 are performed by an assembly device (e.g., a wire bonder or a die bonder).

As shown in FIG. 5, process 500 may include providing a spacer on a first surface of a first component of an optical device (block 510). For example, the device may provide a spacer on a first surface of a first component of an optical device, as described above.

As further shown in FIG. 5, process 500 may include attaching a second surface of a second component of the optical device to the first surface of the first component of the optical device, wherein a solder layer is disposed between a first portion of the first surface and a second portion of the second surface, and wherein the spacer is disposed within the solder layer between the first surface and the second surface (block 520). For example, the device may attach a second surface of a second component of the optical device to the first surface of the first component of the optical device, as described above. In some implementations, a solder layer is disposed between a first portion of the first surface and a second portion of the second surface. In some implementations, the spacer is disposed within the solder layer between the first surface and the second surface.

Process 500 may include additional implementations, such as any single implementation or any combination of implementations described below and/or in connection with one or more other processes described elsewhere herein.

In a first implementation, attaching the second surface to the first surface comprises compressing the first surface toward the second surface to squeeze at least a portion of the solder layer out from an area between the spacer and the second surface, such that the spacer becomes at least partially disposed in the solder layer.

In a second implementation, alone or in combination with the first implementation, attaching the second surface to the first surface comprises maintaining the first surface and the second surface substantially in parallel until the solder layer hardens.

In a third implementation, alone or in combination with one or more of the first and second implementations, process 500 includes attaching a solder preform to the second surface to form the solder layer, and attaching the second surface to the first surface comprises attaching the second surface to the first surface based on attaching the solder preform to the second surface.

In a fourth implementation, alone or in combination with one or more of the first through third implementations, attaching the second surface to the first surface comprises heating the spacer and the solder layer to a first temperature to melt the solder layer, and forming an inter-diffused intermediate material at an interface of the solder layer and the spacer based on heating the spacer and the solder layer to the first temperature to melt the solder layer, the inter-diffused intermediate material having a second temperature for melting that is higher than the first temperature.

In a fifth implementation, alone or in combination with one or more of the first through fourth implementations, process 500 includes providing another spacer on a third surface of a third component of the optical device, attaching a second surface of the second component of the optical device to the third surface of the third component of the optical device, wherein another solder layer is disposed between at least part of the third surface and the second surface, and wherein the other spacer is disposed within the other solder layer between at least part of the third surface and the second surface, and maintaining the first solder layer at less than the second temperature to maintain the inter-diffused intermediate material in a solid state to hold a position of the first surface relative to the second surface.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical device, comprising:
a base with a first coefficient of thermal expansion (CTE); and
an opto-mechanical component with a second CTE attached to a surface of the base via a solder layer, and
wherein a spacer is disposed within the solder layer to attach the opto-mechanical component to the base.

2. The optical device of claim 1, wherein the first CTE and the second CTE differ by greater than a threshold amount

3. The optical device of claim 1, wherein the opto-mechanical component includes at least one of: a fiber mount, a carrier, a prism, a lens, a waveguide device, a metal layer, or a chip-on-submount (CoS).

4. The optical device of claim 1, wherein opposing surfaces of the base and the opto-mechanical component are substantially parallel.

5. The optical device of claim 1, wherein a thickness of the solder layer is less than approximately 10 micrometers.

6. The optical device of claim 1, wherein a spacing between the base and the opto-mechanical component is based on a thickness of the spacer.

7. The optical device of claim 1, wherein the spacer includes at least one of: gold, nickel, aluminum, or dielectric.

8. The optical device of claim 1, wherein the spacer is independent of the base and the opto-mechanical component.

9. The optical device of claim 1, wherein the spacer is a pillar structure attached to or formed from a portion of the base or the opto-mechanical component.

10. The optical device of claim 1, wherein a plurality of discrete spacer sections, of the spacer, form a plurality of attachment points between the base and the opto-mechanical component.

11. The optical device of claim 1, further comprising: an inter-diffused material layer formed at an interface between two other layers, wherein the two other layers comprises a first material and a second material that is metallic and is different from the first material.

12. The optical device of claim 11, wherein the first material is associated with a first melting temperature and the second material is associated with a second melting temperature, and
wherein the inter-diffused material layer comprises a third material is present at the interface of the first material and the second material,
the third material being an alloy of at least one component of the first material and at least one component of the second material,
the third material having a third melting temperature that is higher than the first melting temperature and the second melting temperature.

13. A method, comprising:
providing a spacer on a first surface of a first component of an optical device; and
attaching a second surface of a second component of the optical device to the first surface of the first component of the optical device,
wherein a solder layer is disposed between a first portion of the first surface and a second portion of the second surface, and
wherein the spacer is disposed within the solder layer between the first surface and the second surface.

14. The method of claim 13, wherein attaching the second surface to the first surface comprises:
compressing the first surface toward the second surface to squeeze at least a portion of the solder layer out from an area between the spacer and the second surface, such that the spacer becomes at least partially disposed in the solder layer.

15. The method of claim 13, wherein attaching the second surface to the first surface comprises:
maintaining the first surface and the second surface substantially in parallel until the solder layer hardens.

16. The method of claim 13, further comprising:
attaching a solder preform to the second surface to form the solder layer; and
wherein attaching the second surface to the first surface comprises:
attaching the second surface to the first surface based on attaching the solder preform to the second surface.

17. The method of claim 13, wherein attaching the second surface to the first surface comprises:
heating the spacer and the solder layer to a first temperature to melt the solder layer; and
forming an inter-diffused intermediate material at an interface of the solder layer and the spacer based on heating the spacer and the solder layer to the first temperature to melt the solder layer, the inter-diffused intermediate material having a second temperature for melting that is higher than the first temperature.

18. The method of claim 17 further comprising:
providing another spacer on a third surface of a third component of the optical device;
attaching the first surface of the first component of the optical device to the third surface of the third component of the optical device,
wherein another solder layer is disposed between at least part of the third surface and the first surface, and
wherein the other spacer is disposed within the other solder layer between at least part of the third surface and the first surface; and
maintaining the solder layer at less than the second temperature to maintain the inter-diffused intermediate material in a solid state to hold a position of the first surface relative to the second surface.

19. An optical device, comprising:
a base with a first coefficient of thermal expansion (CTE);
a fiber mount with a second CTE attached to a surface of the base via a first solder layer,
wherein the first CTE and the second CTE differ by greater than a threshold amount, and
wherein a first set of spacers is disposed within the first solder layer to attach the fiber mount to the base; and
a chip-on-submount (CoS) with a third CTE attached to the surface of the base via a second solder layer,
wherein the first CTE and the third CTE differ by greater than the threshold amount, and
wherein a second set of spacers is disposed within the second solder layer to attach the CoS to the base.

20. The optical device of claim 19, wherein spacers of the first set of spacers and the second set of spacers are formed from a gold material.

21. The optical device of claim 19, wherein spacers of the first set of spacers and the second set of spacers are cylindrically shaped.

22. An optical device, comprising:
a base with a first coefficient of thermal expansion (CTE);
a first opto-mechanical component with a second CTE attached to a surface of the base via a first solder layer,
wherein the first CTE and the second CTE differ by greater than a threshold amount, and
wherein a first spacer is disposed within the first solder layer to attach the first opto-mechanical component to the base; and
a second opto-mechanical component with a third CTE attached to the surface of the base via a second solder layer,
wherein the first CTE and the third CTE differ by greater than the threshold amount, and
wherein a second spacer is disposed within the second solder layer to attach the second opto-mechanical component to the base.

23. The optical device of claim 22, further comprising:
a layer of an intermetallic compound formed between the first spacer and the first opto-mechanical component as a product of attaching the first opto-mechanical component to the base using the first solder layer in a presence of the first spacer,
wherein the layer of the intermetallic compound maintains a position of the first opto-mechanical component relative to the base at a temperature associated with attaching the second opto-mechanical component to the base using the second solder layer.

24. The optical device of claim 22, further comprising:
a first emitter attached to the first opto-mechanical component; and
a second emitter attached to the second opto-mechanical component.

25. The optical device of claim 24, wherein an alignment tolerance for the first emitter and the second emitter is less than a threshold amount.
